(19) United States
(12) Patent Application Publication
(10) Pub. No.: US 2021/0192099 A1
(43) Pub. Date: Jun. 24, 2021

(54) METHOD AND SYSTEM FOR GENERATING AN ADAPTIVE PROJECTED REALITY IN CONSTRUCTION SITES

(71) Applicant: LIGHTYX SYSTEMS LTD, Tel Aviv (IL)

(72) Inventors: Guy Shlomo BENROMANO, Tel Aviv (IL); Uri YEHUDAY, Holon (IL)

(73) Assignee: LIGHTYX SYSTEMS LTD, Tel Aviv (IL)

(21) Appl. No.: 16/622,561

(22) PCT Filed: Jun. 14, 2018
(86) PCT No.: PCT/IL2018/050653

§ 371 Date: Dec. 13, 2019

Related U.S. Application Data
(60) Provisional application No. 62/519,594, filed on Jun. 14, 2017.

(51) Int. Cl. G06F 30/13; G06Q 50/08; G06T 17/05

(52) U.S. Cl. CPC G06F 30/13; G06T 2210/04; G06T 17/05; G06Q 50/08

(57) ABSTRACT

A method and a system for projecting an adaptive augmented reality content over a dynamically changing construction site are provided herein. The system may include: a capturing device comprising at least one sensor configured to capture 3D images of a scene; a computer processor configured to: generate a 3D model of surfaces within said scene, based on said captured 3D images; and obtain a construction plan associated with a construction to be built in said scene; generate projectable visual content based on a desired state of construction based on the construction plan and a current state of the construction based on said 3D model of surfaces within said scene; and a projector configured to project said projectable visual content onto said surfaces within said scene, wherein said capturing device, said computer processor, and said projector are configured to repeat their operation and update said projectable visual content.

### FIELD OF THE INVENTION

The present invention relates generally to the field of adaptive projected reality and more specifically, adaptive projected reality for use in dynamically changing scenes.

### BACKGROUND OF THE INVENTION

A typical construction process involves two principal stages, namely a design stage and a build stage. In the design stage, an architect typically plans the layout and composition of a structure and possibly proposes a construction timeframe or schedule. In the build stage, a contractor, possibly assisted by a team of builders, implements the architectural plan and thereby builds the structure according to the specification and schedule provided.

In order to ensure that the resultant structure matches the architectural plans as closely as possible, build stages are often very slow and may entail a plurality of surveyors regularly assessing and measuring the structure to obviate the emergence or continuation of plan divergence. This is generally important as, should significant unintended plan divergence occur, there may be limited opportunity to rectify the structure later on during the build cycle. In particular, certain levels of plan divergence could impede structural integrity and moreover necessitate substantial modification, overhaul or even rebuild. In some circumstances, particularly where there are strict timeframes or budgets at play, plan divergence may be prohibitively expensive or timely to rectify and moreover could result in the construction project being completed late, over-budget and/or remain unfinished.

In order to improve build accuracy and efficiency, a number of known electronic devices are often employed during build projects, such as laser distance meters and three-dimensional (3D) reconstruction tools. These electronic devices are however cumbersome and sometimes unwieldy to use, and moreover often address localized, rather than macroscopic, aspects of the construction. In circumstances where build optimization or reorganization has been performed in isolation of the construction as a whole, misalignment issues have an increased likelihood to develop later on during the build cycle. Accordingly, it is an object of the invention to propose a means for improving build accuracy and efficiency in construction projects. It is a further object of the invention to propose a means for macroscopically assessing build divergence and adaptively improving build quality in dynamic build environments.

### SUMMARY OF THE PRESENT INVENTION

Some embodiments of the invention provide a system for projecting an adaptive augmented reality content over a dynamically changing construction site. The system may comprise: a capturing device comprising at least one sensor configured to capture 3D images of a scene; a computer processor configured to: generate a 3D model of surfaces within said scene, based on said captured 3D images; and obtain a construction plan associated with a construction to be built in said scene; generate projectable visual content based on a desired state of construction based on the construction plan and a current state of the construction based on said 3D model of surfaces within said scene; and a projector configured to project said projectable visual content onto said surfaces within said scene, wherein said capturing device, said computer processor, and said projector are configured to repeat their operation and update said projectable visual content.

Alternative embodiments of the invention provide a method for projecting adaptive augmented reality content over a dynamically changing construction site. The method may comprise: capturing, using a capturing device, 3D images of a scene; generating a 3D model of surfaces within said scene, based on said 3D images of said scene; obtaining a construction plan associated with a construction to be built in said scene; generating projectable visual content based on: a desired state of construction based on the construction plan; and, a current state of the construction based on said 3D model of surfaces within said scene; and projecting said projectable visual content onto said surfaces within said scene, wherein said capturing, said obtaining, said generating, and said projecting are repeated to update said projectable visual content.

These and other features of the present invention are set forth in detail in the following description.

### BRIEF DESCRIPTION OF THE DRAWINGS

For a better understanding of the invention and in order to show how it may be implemented, references are made, purely by way of example, to the accompanying drawings in which like numerals designate corresponding elements or sections. In the accompanying drawings:

FIG. 1 is a high-level diagram illustrating a non-limiting system arrangement in accordance with embodiments of the present invention.

FIG. 2 is a high-level diagram illustrating an exemplary implementation cycle in accordance with embodiments of the present invention.

FIG. 3 is a high-level block-diagram illustrating non-limiting exemplary sensing module operation in accordance with embodiments of the present invention.

FIG. 4 is a high-level block-diagram illustrating non-limiting exemplary fitting module operation in accordance with embodiments of the present invention.

FIG. 5 is a high-level block-diagram illustrating non-limiting exemplary projection module operation in accordance with embodiments of the present invention.

FIG. 6 is a high-level diagram illustrating a detailed non-limiting system arrangement in accordance with embodiments of the present invention.

FIG. 7 is a high-level flowchart illustrating a non-limiting exemplary three-dimensional scanning method in accordance with embodiments of the present invention.

FIG. 8 is a high-level block-diagram illustrating a non-limiting exemplary method in accordance with embodiments of the present invention.

### DETAILED DESCRIPTION OF THE INVENTION

With specific reference now to the drawings in detail, it is stressed that the particulars shown are for the purpose of example and solely for discussing the preferred embodiments of the present invention, and are presented in the cause of providing what is believed to be the most useful and readily understood description of the principles and conceptual aspects of the invention. In this regard, no attempt is made to show structural details of the invention in more detail than is necessary for a fundamental understanding of the invention. The description taken with the drawings makes apparent to those skilled in the art how the several forms of the invention may be embodied in practice.

Before explaining the embodiments of the invention in detail, it is to be understood that the invention is not limited in its application to the details of construction and the arrangement of the components set forth in the following descriptions or illustrated in the drawings. The invention is applicable to other embodiments and may be practiced or carried out in various ways. Also, it is to be understood that the phraseology and terminology employed herein is for the purpose of description and should not be regarded as limiting.

Prior to setting forth the detailing description of the invention, the following term definitions are provided.

The term ‘adaptive’ refers generally to capability or susceptibility to undergo accordant change to improve fit or suitability. More specifically, in the present context ‘adaptive’ refers to the capacity of a system or tool to vary its output, for example its projected output, in accordance with a dynamic scene or environmental alterations.

The term ‘augmented reality’ refers generally to a direct or indirect view of a physical real-world environment whose elements have been augmented by overlaid computer-generated perceptual information. This perceptual information may, in particular, be presented using visual modes; however other modalities such as auditory, haptic, somatosensory and olfactory modes may also be employed. Overlaid sensory information may be constructive or destructive and thereby act to additively compliment features present in the environment, or otherwise act to obfuscate and mask features present in the environment.

The term ‘dynamically changing’ refers generally to the character of continual, regular, irregular or constant change, activity or progress. More specifically, in the present context ‘dynamically changing’ refers to environmental changes, for example build progression, arising in correspondence with, or as a consequence of, the passage of time. In some circumstances dynamic changes may be anticipated and may occur in accordance with a plan or schedule. In other circumstances dynamic changes may be unintended and arise as a result of error or in consequence of, for example, unexpected weather events.

The term ‘three-dimensional (3D) point cloud’ refers generally to a set of data points disposed regularly or uniformly throughout a space or environment. Point clouds are typically produced using 3D scanners which measure and characterize the external surfaces of objects in the locality. Point clouds may be used for numerous purposes, most notably including CAD models, metrology, quality inspection, or, as in the present context, visualization, animation and rendering. Point clouds may be converted and rendered into 3D surfaces using numerous known techniques, for example Delaunay triangulation, alpha shapes or ball pivoting. Some of these conversion approaches entail building a network of triangles over existing vertices in the point cloud, while others convert the point cloud into a volumetric distance field and reconstruct implicit surfaces through use of, for example, a marching cube algorithm.

The terms ‘point set registration’ (PSR) or ‘point matching’ refer generally to the pattern recognition process of finding a spatial transformation which aligns two point sets. More specifically, in the present context a spatial transformation may be derived by merging multiple data sets into a globally consistent model and mapping new measurements to a known data set to identify features or to estimate a pose (i.e., position and orientation). In some circumstances, at least one of the point sets may be derived from raw 3D scanning data depicting, for example, a real-world scene and/or a construction site.

The term ‘iterative closest point’ (ICP) refers generally to an algorithm employed to minimize the difference or divergence between two clouds of points. In the present context, a construction plan may be represented as a first target or reference cloud of points that is held fixed. A second cloud of points, possibly derived through scanning 2D or 3D surfaces in a real scene or construction site, may be transformed to best match the target or reference cloud of points. In particular, the algorithm may iteratively revise the transformation, for example in terms of translation and rotation, to minimize an error metric such as the point distance between the two clouds of points.

Turning now to the detailed description, some embodiments of the present invention provide an Adaptive Projected Reality (APR) device for use by, for example, builders, appraisers, architects, engineers, surveyors, inspectors and the like. The APR device may be used to project desired construction plans onto a target surface for the purposes of, for example, improving the accuracy and efficiency with which builders may progress a construction.

The APR device may monitor a local or proximate environment and project instructions or images onto surfaces located therein. The APR device may be capable of adaptively changing and aligning projected images or instructions in correspondence with environmental variations, construction advancement and/or repositioning. In particular, the APR device may vary projected images or instructions based on any of: updated or modified plans; environmental changes; and, changes in device location relative to the environment. In some embodiments the APR device may also provide feedback regarding the progress of a construction, for example with respect to a predefined schedule, or on the quality and accuracy with which the build is progressing, for example with respect to deviation from a predefined build or design plan.

In some embodiments, the APR device may continually or irregularly record build progression, for example in relation to a build schedule, and create status updates. In some embodiments, the status updates may comprise alert or warning information and may be transmitted, for example via wireless means, to relevant predefined internal or external entities. In some embodiments, relevant internal entities may comprise one or more construction employees, for example: workers on site; field supervisors; project manager, or the like. In alternative embodiments, relevant external entities may comprise one or more stake holders, for example: developers; financial entities such as banks; legal entities such as lawyers; municipal or governmental authorities; construction managers; internal and external supervisors; and, project managers. In some embodiments, the alert or warning information may comprise all or some of the following:
a. Information on construction quality;
b. Information on deviance between an actual construction and its associated plans/designs;
c. Information concerning statistical or scheduling deviance/anomalies;
d. Information concerning potential safety problems within the original design or the actual construction; and,
e. Information on size measurements of a specified room or building within the actual construction, for example for real estate tax purposes.

It will be appreciated by those skilled in the art that the APR device is not limited to use in relation to construction and may, in some embodiments, be used for other purposes such as:
a. Car, airplane or other large structure manufacturing;
b. Indoor navigation, such as for mapping site interiors;
c. Gaming, such as for projecting animated characters onto surfaces around a player;
d. Templates, such as for projecting guides onto surfaces for painters to trace or plot; and,
e. Carpentry, such as for installing a cupboard or other furniture onto a wall.

In alternative embodiments, the APR device may be used for post-construction maintenance, renovation and repairs. In particular, should a building fall into disrepair or require extension, for example due to ageing or a fire outbreak, the APR device may be utilized to identify and project the location of conduits (e.g., pipework), electricity cabling and/or other critical building elements, as would be appreciated by those skilled in the art. This may be of particular value where the building elements/cabling/conduits are located behind opaque surfaces, such as walls, bulkheads or the like.

Further, it will be appreciated by those skilled in the art that reference to ‘construction site’, as used herein, may refer interchangeably to any form of commercial or private real estate. Non-limiting examples of commercial or private real estate include: new buildings, rehabilitated building, houses, apartments, or any other appropriate form of infrastructure. Further, reference to “as built” or “as made” may refer to the resultant form of a constructed structure/building, or portion thereof. It will be appreciated that a structure “as built” may have poor, adequate or optimal adherence to a construction plan.

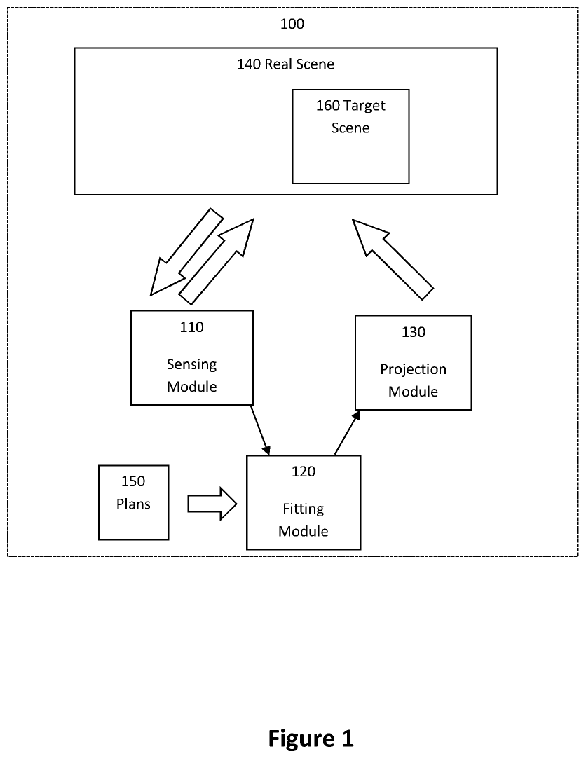

FIG. 1 is a high-level diagram illustrating a non-limiting system arrangement 100 configured to perform sensing, fitting and projection according to embodiments of the invention. System 100 may include a sensing module 110 comprising one or more sensors, for example one or more 2D and/or 3D cameras, global positioning systems (GPS), inertial measurement units (IMU), or the like. In alternative embodiments, the one or more sensors may be passive and/or active sensors, for example light detection and ranging sensors (LiDAR), radio frequency sensors (RF), or ultrasonic radar sensors. Sensing module 110 may also comprise one or more signal processors, for example one or more digital signal processors (DSP), advanced RISC machine (ARM), or any other processor as would be appreciated by those skilled in the art. Sensing module 110 may measure the distance between the APR device and the surface of features and objects around it, and therefrom produce a 3D point cloud representative of the 3D coordinates of features and objects present in the field of view (FOV) of the sensing module 110. In some embodiments, the 3D point cloud may be used to map the real scene environment 140, localize the APR device within the real scene environment 140, and/or orientate the APR device relative to the real scene environment 140.

In some embodiments, images captured by the one or more 2D and/or 3D cameras may be stored on the APR device and/or on an external cloud server for subsequent processing, for example: to identify safety hazards and/or for the purposes of project monitoring and tracking.

In some embodiments, the real scene 140 may take the form of any real-world environment or any place surrounding or encompassing the APR device. Non-limiting examples of real scenes 140 include: rooms, hallways, parking lots, gardens, and the like.

In some embodiments, system 100 may further comprise a fitting module 120. Fitting module 120 may be operable to receive data recorded by sensing module 110 and may further receive plans data 150. In some embodiments, plans data 150 may be transmitted to fitting module 120 through wired or wireless means, as will be appreciated by those skilled in the art. Fitting module 120 may correlate the 3D point cloud and/or other information received from sensing module 110 (e.g. additional mapping, localization, and/or orientation data) with plans data 150. This may entail fitting module 120 acting to align, fit and/or match plans data 150 with the real scene 140 represented by the 3D point cloud. Based on this fitting, fitting module 120 may calculate a correlated visible image for output by a projection module 130.

It will be appreciated by those skilled in the art that the fitting process may be completed by any of: fitting, aligning or matching plans data 150 onto/into the real scene 140 represented by the 3D point cloud; fitting, aligning or matching the real scene 140 represented by the 3D point cloud onto/into the plans data 150; or, by any other appropriate method or combination thereof. Further, it will be appreciated by those skilled in the art that the fitting process, or PSR, may be conducted using any known method, such as ICP or visual positioning system (VPS) techniques.

In some embodiments, the fitting process may be expediated or assisted through use of known or predefined objects/points with quantified locations within, or relative to, the real scene 140. In some embodiments, known or predefined objects/points may be measured separately or in advance, and may be used as reference points about which the APR device may ascertain its orientation and/or location within, or relative to, the real scene 140. In particular, walls, immovable objects and/or other scene features may be marked or denoted as anchors and may be used as reference points.

In some embodiments, system 100 may further comprise a projection module 130. Projection module 130 may comprise one or more means for light projection, for example laser projection, light emitting diode (LED) projection, or the like. In some embodiments, projected light may be visible or non-visible light and may comprise different wavelengths, possibly including infra-red (IR) or near infra-red (NIR) light. In alternative embodiments, the projected light may be combination of visible and non-visible light. Projection module 130 may be operable to receive desired image data and/or correlated visible images from fitting module 120 and may project said data/images onto a target scene 160. In further embodiments, correlated visible images may be calculated by fitting module 120 and may include various forms of information, possibly including portions of plans data 150, or any other appropriate information as would be apparent to those skilled in the art.

In some embodiments, plans data 150 may comprise computer aided design (CAD) sketches, Geographic Information Systems (GIS), graphical images, text, arrows, user defined information, and the like. Plans data 150, or portions thereof, may also comprise building information modeling (BIM) and may include digital descriptions of aspects of the built asset, for example aspects of 3D structures, time schedules, costs, and the like. In some embodiments, sensing module 110 and projection module 130 may operate simultaneously, or substantially simultaneously. In alternative embodiments, sensing module 110 and projection module 130 may be operated independently and/or at separate times or intervals.

In some embodiments, target scene 160 may be a subset or portion of real scene 140. In particular, target scene 160 may comprise any place, surface or object within the real scene 140, for example and not limited to: a wall, ceiling, floor, screen, or the like. In alternative embodiments, target scene 160 may comprise all, or substantially all, of real scene 140.

In some embodiments, sensing module 110, fitting module 120, and projection module 130 may be implemented in the same unitary or composite device. In alternative embodiments, sensing module 110, fitting module 120, and projection module 130 may be implemented on separate or discrete devices. For example, the sensing module 110 and projection module 130 may be placed in one position while fitting module 120 may be placed on an external laptop or in the cloud.

In some embodiments, sensing module 110, fitting module 120, and projection module 130 may share the same components. For example, sensing module 110 may use active light beam projection for scanning the real scene 140 and may be implemented, for example, using steering mirrors or the like. Projection module 130 may similarly use visible light beam projection for projecting the visual image. In such instances, the sensing module 110 and projection module 130 may share the same steering mirrors.

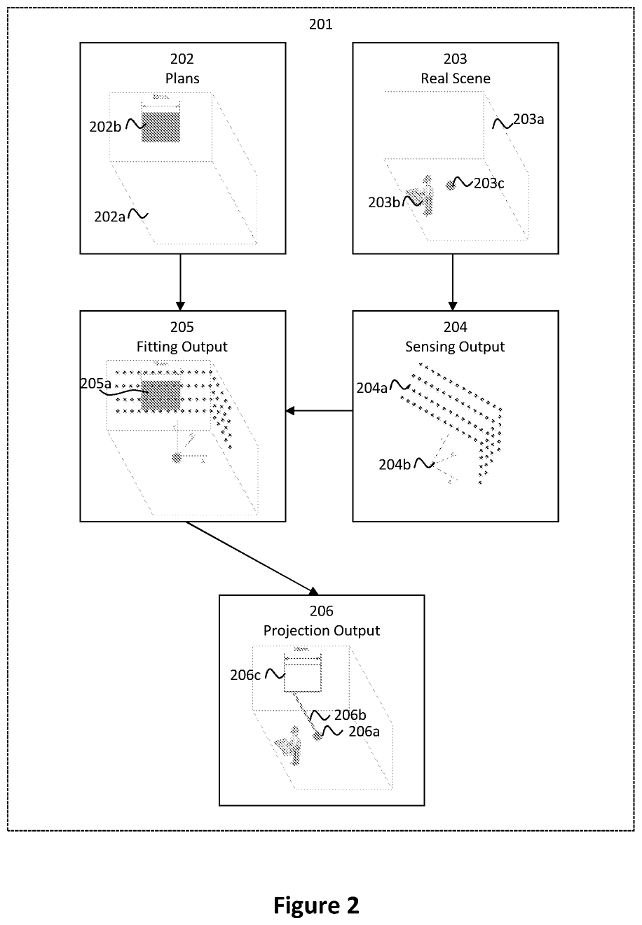

FIG. 2 is a high-level diagram illustrating an exemplary implementation cycle 201 according to embodiments of the invention. Section 202 depicts example plans data 150 for implementation into a cubic room construction plot 202a. Specifically, in this example the illustrated plans data 150 includes adding a window 202b to a distal wall in the cubic room construction plot 202a.

Section 203 depicts the real scene 140 prior to the addition of window 202b. In this illustration, the construction environment, namely the cubic room 203a, has already been partially built and comprises a number of fully constructed walls. A worker 203b, who is charged with cutting a hole and installing window 202a into the distal wall, begins by positioning an APR device 203c within the construction environment (i.e. within cubic room 203a).

Section 204 depicts the output of an exemplary sensing module 110 of APR device 203c. The output may include a 3D point cloud 204a according to device mapped and/or localized coordinate axes 204b relative to cubic room 203a.

Section 205 depicts the output of an exemplary fitting module 120 of APR device 203c. The fitting module 120 receives plans data 150 and output data from sensing module 110 (i.e., the 3D point cloud 204a) and correlates the two. In particular, the output data from sensing module 110 is aligned with the coordinate system of plans data 150 to yield correlated data 205a.

Section 206 depicts the output an exemplary projection module 130 of APR device 206a. The projection unit of APR device 206a projects a light beam 206b into the construction environment, specifically onto the distal wall of cubic room 203a, and thereby plots the correlated data 205a (i.e., window 206c) for worker 203b to use as a cutting and installation guide. In some embodiments, the projection may include other information, possibly including the size and height of the window 206c, to further assist worker 203b.

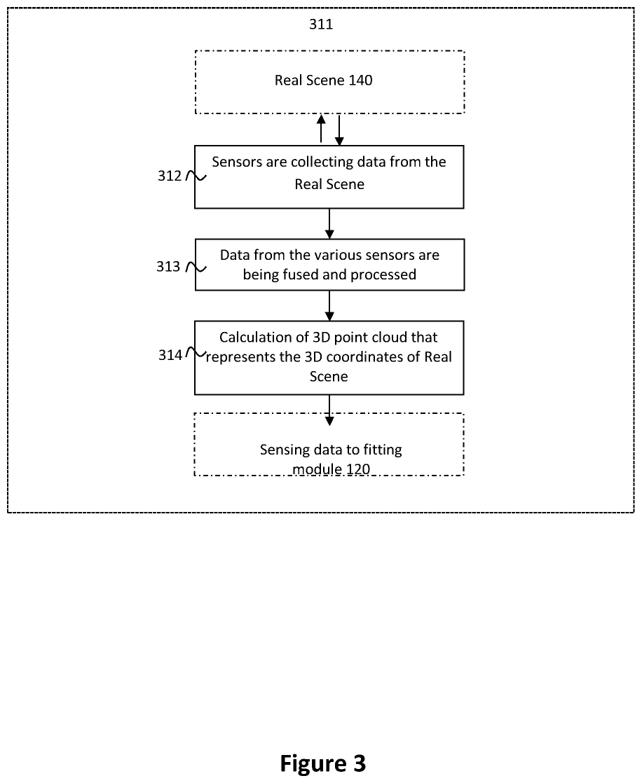

FIG. 3 is a high-level block-diagram illustrating non-limiting exemplary sensing module operation 311 according to embodiments of the invention. In some embodiments, step 312 comprises using sensors to collect data from the real scene 140; step 313 comprises fusing and processing data from the sensors; and, step 314 comprises generating, from the fused and processed data, a 3D point cloud representative of said real scene 140. In some embodiments, the 3D point cloud may represent the 3D coordinates of the entirety of real scene 140. In alternative embodiments, the 3D point cloud may represent the 3D coordinates of a subset or portion of real scene 140. In some embodiments, all or part of the fused and processed data and/or the 3D point cloud are sent to fitting module 120.

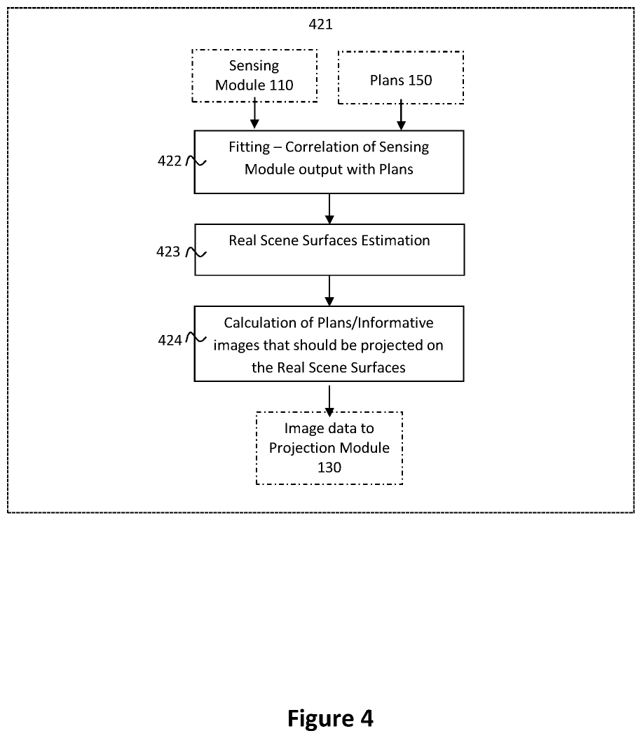

FIG. 4 is a high-level block-diagram illustrating non-limiting exemplary fitting module operation according to embodiments of the invention. In some embodiments, step 422 comprises correlating the output data from sensing module 110 with the plans data 150. In some embodiments, the output data from sensing module 110 may be representative of real scene 140, and the plans data 150 may be representative of the desired design plans. The correlation between the output data of sensing module 110 and the plans data 150 may be used to align the plans data with the real scene 140 environment.

In some embodiments, step 423 comprises estimating the surfaces of the real scene 140; and, step 424 comprises calculating an image for projection on the real scene 140 surfaces. In some embodiments, surface estimation conducted in step 423 may be completed prior to the fitting conducted in step 422. This may be advantageous where it is desirable for the correlation to account for surface estimation instead of, or in addition to, the output data from sensing module 110. In some embodiments, all or part of the calculated images for projection onto real scene 140 surfaces are sent to projection module 130.

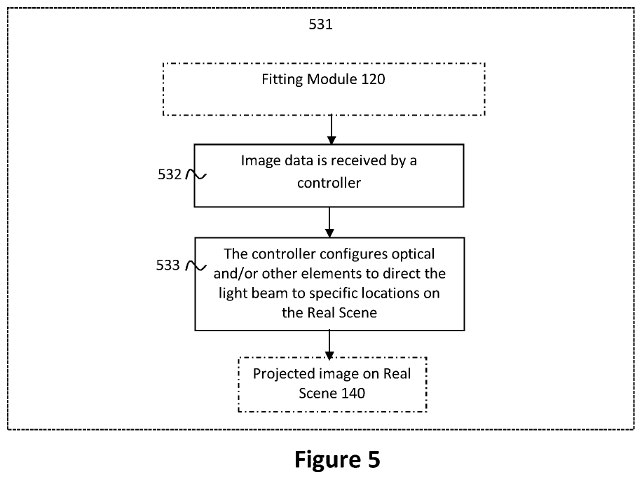

FIG. 5 is a high-level block-diagram illustrating non-limiting exemplary projection module operation according to embodiments of the invention. In some embodiments, step 532 comprises receiving, at a controller, image data from fitting module 120; and, step 533 comprises configuring, using the controller, optical and/or other elements to direct a light beam to specific locations within real scene 140. In some embodiments, the directed light beam projects and renders an image or information onto surfaces within real scene 140.

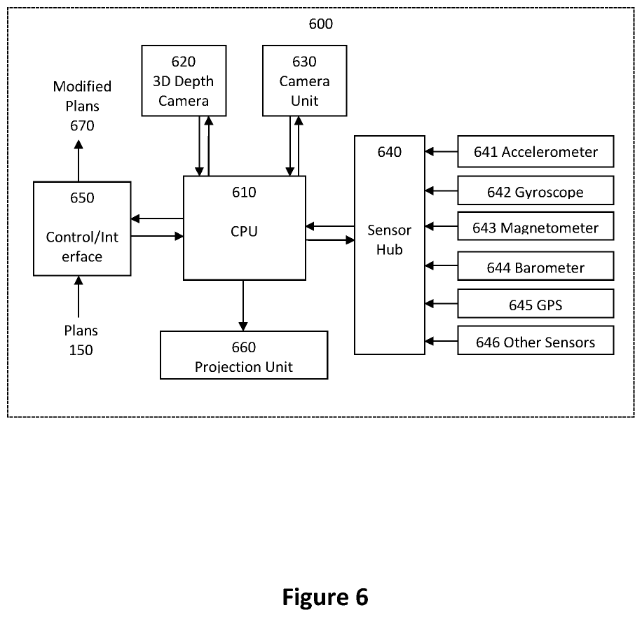

FIG. 6 is a high-level diagram illustrating a detailed non-limiting APR system arrangement 600 according to embodiments of the invention. In some embodiments, APR system arrangement 600 comprises a 3D depth camera 620 operable to scan a real scene 140 proximate to the system. 3D depth camera 620 may be, for example, a laser projected to specific locations using light beam steering optics (e.g., micro electro mechanical sensor (MEMS) mirrors, digital light processing (DLP), or the like). Light reflected from surfaces within the real scene 140 may be captured using reception sensors included in 3D depth camera 620. The actuation, configuration and orientation of 3D depth camera 620 may be selectively or continually controlled by a central processing unit (CPU) 610. In some embodiments, information obtained and/or received by 3D depth camera 620 may be sent to and/or processed by CPU 610. In alternative embodiments, 3D depth camera may be, for example, a stereo camera, a structured light camera, an active stereo camera, a time of flight (TOF) camera, a LiDAR based camera, a CMOS image sensor based camera, or any other appropriate camera as would be apparent to those skilled in the art.

In some embodiments, APR system arrangement 600 may further comprise a camera unit 630 operable to monitor and scan a proximate and/or surrounding area. Camera unit 630 may comprise one or more cameras, for example one or more high definition (HD) and/or IR cameras. Camera unit 630 may be controlled by CPU 610 and/or may send recorded/measured data to CPU 610 for processing.

In some embodiments, APR system arrangement 600 may further comprise a sensor hub 640 operable to receive information from one or more different sensors, for example: one or more accelerometers 641 operable to measure acceleration of the APR system arrangement 600; one or more gyroscopes 642 operable to measure orientation of the APR system arrangement 600; one or more magnetometers 643 operable to measure magnetism around the APR system arrangement 600; one or more barometers 644 operable to measure atmospheric pressure around the APR system arrangement; one or more Global Positioning Systems (GPS) operable to measure location of the APR system arrangement 600; one or more other sensors 646, for example one or more IR detectors; and/or, any combination thereof. In some embodiments, measurement data received from the one or more different sensors are processed by the sensor hub 640 and relevant and/or processed information may be sent to CPU 610 for further processing/analysis. In alternative embodiments, CPU 610 may be operable to control sensor hub 640.

In some embodiments, APR system arrangement 600 may further comprise a control/interface unit 650 operable to control functionality of the APR system arrangement 600. In some embodiments, control/interface unit 650 may be included within, or as part of, the APR system arrangement 600 (i.e. as part of a unitary or composite system structure). In alternative embodiments, control/interface unit 650 may be disposed externally from the APR system arrangement 600, for example embodied as a computer, laptop, mobile device, iPad, or the like, and may be interconnected with the APR system arrangement 600 via wired or wireless means, for example via Bluetooth, Wi-Fi, or the like. In yet further embodiments, control/interface unit 650 may be both external to, and included within, the APR system arrangement 600, for example where there are multiple control/interface units 650 and/or where there is a selectable/variable insertion/interconnectivity means. In some embodiments, control/interface unit 650 may communicate with other devices, internet of things (IoT) devices, cloud computing/connectivity services, or the like. In some embodiments, control/interface unit 650 may further comprise one or more: radio frequency identification (RFID) readers; one or more bar-code readers; or, any other information reading device as would be appreciated by those skilled in the art. Control/interface unit 650 may also comprise a user interactable interface via which configuration commands/controls may be input/issued to define APR system arrangement 650 functionality.

In some embodiments, control/interface unit 650 may receive plans data 150 and may send relevant portions and/or all of the data to CPU 610. In alternative embodiments, CPU 610 may directly receive plans data 150, for example without intermediate connection and/or processing. In some embodiments, control/interface unit 650 may comprise an input device, for example a screen, touch screen, mouse, keyboard, or the like, which may be used by a user to configure the APR system arrangement 600. In some embodiments, control/interface unit 650 may determine/calculate 3D sensing and projection methods/parameters and/or information/images for projection into the real scene 140. In alternative embodiments, CPU 610 may provide/send information/data about the APR system arrangement 600 to control/interface unit 650, for example including scanned information, projected information, sensor measurements, and the like. In yet further embodiments, plans data 150 may be uploaded to the APR system arrangement 600 via wired or wireless means, for example via USB stick or by download from a cloud computing server.

In some embodiments, control/interface unit 650 may be operable to create modified plans data 670 based on original plans data 150. Modified plans data 670 may be determined or generated according to a deviation/misalignment/misfit between the measured real scene 140 and the original plans data 150. In some embodiments, a user may decide, for example via a warning or prompt, whether to accept a measurement of real scene 140. In the event that this measurement is not accepted, the user may instruct the control/interface unit 650 to conduct a supplementary measurement of real scene 140. In the event that the measurement is accepted, the user may additionally decide, for example via a supplementary warning or prompt, whether to automatically determine or generate modified plans data 670, for example because there is significant misfit between the original plans data 650 and the real scene 140. In alternative embodiments, the user may manually change the original plans data 150 using the control/interface unit 650 to generate modified plans data 670.In alternative embodiments, the modified plans data 670 may be downloaded or retrieved from the APR system arrangement 600 via wired or wireless means, for example via USB stick or by upload to a cloud computing server. In yet further embodiments, modified plans data 670 may presented or displayed graphically on control/interface unit 650 and may be selectively modified using the user interactable interface.

In some embodiments, APR system arrangement 600 may further comprise a central processing unit (CPU) 610 embodied, for example, as a dedicated processor such as an ARM, DSP, or the like. In some embodiments, CPU 610 may receive data/information from at least one of: the 3D depth camera 620; the camera unit 630; the sensor hub 640; and, the control/interface unit 650. In some embodiments, CPU 610 may use received data/information in conjunction with one or more algorithms, for example correlations, registration, simultaneous localization and mapping (SLAM), image detection, and the like, to create/generate one or more projection images/information. In some embodiments, created/generated projection images/information may be sent to projection unit 660 for projection into the real scene 140. Projection images/information may, for example, be sent from CPU 610 to projection unit 660 in an International Laser Display Association (ILDA) compliant image data transfer format.

In some embodiments, CPU 610 may control/instruct camera unit 630 and/or any other sensors, for example IR sensors, to detect humans and/or other specific objects in proximity to the APR system arrangement 600. In the event that a positive determination is made, for example where a human is detected proximate to the APR system arrangement 600, CPU 610 may deactivate/disable the projection unit 660 for safety reasons. In some embodiments, CPU 610 may only partially deactivate/disable the projection unit 660, for example only in the direction/area where the human and/or specific object has been detected.

In some embodiments, CPU 610 may control/instruct camera unit 630 and/or any other sensors, for example IR sensors, to detect humans and/or specific objects and their respective position/location relative to the APR system arrangement 600. In the event that a human and/or specific object is detected proximate to the APR system arrangement 600, CPU 610 may emit/present an alert/warning when the human and/or specific object is within a specific region. The alert/warning may be emitted/presented in any manner as would be appreciated by those skilled in the art, for example in the form of an audible beep, howl, speech, indication, sound or the like. In alternative embodiments, the alert may be presented visually using the projection unit 660, for example in the form of visual alert signs projected into the real scene 140. In yet further embodiments, the alert may additionally/alternatively be transmitted to relevant individuals outside the scene, for example managers, inspectors, or the like, via control/interface unit 650 using one or more communication protocols, for example using WiFi, Bluetooth (BT), cellular, or the like.

In some embodiments, CPU 610 may use data from one or more of: accelerometer 641, gyroscope 642, and/or any other sensor, in combination/correspondence with a stabilizer algorithm to compensate for movements/vibrations of the APR system arrangement 600 and/or any of 3D depth camera 620, camera unit 630, and projection unit 660. In particular, where the APR system arrangement 600 and/or any of 3D depth camera 620, camera unit 630, and projection unit 660 are held, for example by hand, stabilizer algorithms may be used to compensate for vibrations/movements and thereby correct projections and/or sensed data relating to the real scene 140. In alternative embodiments, information and/or data received by sensor hub 640, for example from accelerometer 641 and/or gyroscope 642, may be used by CPU 610 to estimate a 3D orientation and/or movement of APR system arrangement 600 within real scene 140. This may improve the efficacy and/or efficiency of other algorithms/processes conducted by CPU 610, for example SLAM, registration, and the like.

In some embodiments, APR system arrangement 600 may further comprise a built-in level sensor, for example a gravity level. In some embodiments, CPU 610 may use information/data from the level sensor to align one or more of: 3D depth camera 620; camera unit 630; and, projection unit 660.

In some embodiments, images/information projected by projection unit 660 may also be transmitted and displayed, for example via a liquid crystal display (LCD), on one or more mobile devices. In alternative embodiments, images/information transmitted to the one or more mobile devices may be augmented with camera views/images obtained using the mobile device, for example via augmented reality. In yet further embodiments, the information/images displayed on the mobile device may differ from the information/images projected into the real scene 140 by projection unit 660.

In some embodiments, the images/information generated/determined by the control/interface unit 650 and projected by the projection unit 660 may be dynamically and adaptively changed according to progress of the construction. In particular, the images/information may be sequentially or continually updated in correspondence with an ongoing construction, for example to guide a builder through multiple different phases of a large multi-part construction project. In alternative embodiments, the images/information generated/determined by the control/interface unit 650 and projected by the projection unit 660 may be automatically or selectively modified, possibly in conjunction with a user input, by the CPU 610, for example where there is divergence between real scene 140 and plans data 150. The images/information may be modified using optimization algorithms assessing one or more of: deviation between real scene 140 and plans data 150; building standards; work protocols; and the like.

In some embodiments, the APR device may track its location relative to a real scene 140, for example a room/apartment, using sensing module 110 and fitting module 120. In alternative embodiments, the APR device may be preconfigured, or user configured, with a plurality of plans, each associated with a unique reference designation. Each reference designation may relate to a unique floor/apartment/room number and may be used by the APR device to ensure that the correct plan is associated with the correct real scene 140, for example in very large construction projects where each room has a substantially similar composition/layout. In alternative embodiments, each floor/apartment/room may comprise a locator device which the APR device may use to identify its location. In some embodiments, locator devices may comprise one or more of:
a. Bluetooth beacons operable to send location information to the control/interface unit 650;
b. RFID stickers that may be read by an RFID reader in the control/interface unit 650; and,
c. Bar-Code information that may be read by a camera, for example camera unit 630, interconnected with control/interface unit 650.

In yet further embodiments, the APR device may use barometer 644, GPS 645, and/or indoor navigation sensor 646 to determine the APR device's position relative to, or within, a large-scale real scene 140 and thereby upload/access the correct plans data 150.

In some embodiments, the APR device may be moved manually by a user or automatically by motor, and may determine an accurate position relative to, or within, a building/room/structure while in transit. In some embodiments, the APR device may use known or predetermined object/point locations as reference points. These reference points may be used by the APR device, in conjunction with appropriate algorithms, to determine orientation and/or location within the real scene 140. In some embodiments, reference points may comprise walls and/or other objects marked in planning schemes, for example plans data 150, as anchor objects.

In some embodiments, the APR device may be operable to detect, via any appropriate sensor such as accelerometer 641, gyroscope 642, or the like, whether the APR device has been moved. The APR device may be further operable to generate movement alerts in the event that device movement is detected, and thereby alert a user that the device has been moved and that the sensing position and/or projection is no longer accurate. In alternative embodiments, misalignment/misfit caused by movement of the APR device may be ameliorated by automatic rectification of the projected images/information, for example by automatically repeating and/or re-preforming the sensing/imaging and/or fitting processes, as discussed herein. In alternative embodiments, the APR device may be fixedly connected to a dedicated or ‘off-the-shelf’ tripod to improve stability and limit movement. In alternative embodiments, the APR device may be fixedly or removably connected to a dedicated movable vehicle and/or robot. The movable vehicle and/or robot may be controlled manually by a user or automatically in correspondence with, for example, sensor data. The movable vehicle and/or robot may be operable to vary alignment of projected images/information according to construction advancement and/or as a result of blocking/intervening objects in the projection field of view (FOV).

In some embodiments, the APR device may further comprise a screen, for example an LCD display, for presenting mixed/augmented reality images/information on the body of the APR device itself. In alternative embodiments, the screen may be a transparent screen.

In some embodiments, the APR device may further comprise one or more microphones. These microphones may be operably connected to a processing unit, for example CPU 610, and may use speech recognition algorithms, such as automatic speech recognition (ASR) algorithms and/or natural language processing (NLP) algorithms, to detect and ascertain/comprehend voice commands from a user. This may enable the user to issue control commands to the APR device from a distance and thereby, for example, operate the APR device while standing on a ladder, or the like. In alternative embodiments, the APR device may comprise one or more remote controllers. These remote controllers may also enable the user to issue control commands to the APR device from a distance, for example while the worker is standing on a ladder, or the like.

In some embodiments, the APR device may be used in conjunction with glasses, for example standard spectacles or the like, comprising enhancement filters. In some embodiments, these enhancement filters may be light filters tailored to match and improve visibility, for example due to sun glare, of images/information projected by projection unit 660.

In some embodiments, the APR device may be utilized onboard a moving vehicle/robot/drone to scan each floor/room of a structure and build map thereof. In some embodiments, the APR device may guide a robot to perform a specific task, for example painting a wall, cleaning the floor, or the like, using the projection unit 660. In particular, light projected by the projection unit 660 may be used as a trace or guide about which the robot may move and complete its task. The progress of the task and/or the robot's movement may be tracked using the 3D depth camera 620 and/or the camera unit 630.

In some embodiments, the APR device may further comprise an internal/external audio speaker interconnected with control/interface unit 650. In some embodiments, the audio speaker may play different sounds to, for example:
a. Alert/warn a user or any other person/worker near the device; and,
b. Provide guidance and instructions that explain the task or the projected images/information.

In some embodiments, multiple APR devices may be wirelessly interconnected as IoT devices, for example via a cloud computing server, and share data/information therebetween. The control/interface unit 650 in each APR device may be used to send and receive data/information from the cloud. In alternative embodiments, multiple APR devices may be directly connected to one another, for example via wired or wireless means, using control/interface unit 650. In particular, interconnectivity between APR devices enables them to be spread throughout, for example, a large construction site without loss of information/data exchange, thereby improving the accuracy and/or efficiency with which a construction may progress.

In some embodiments, the APR device may communicate with other external APR devices, for example a stand-alone APR device, and may send information/images to be projected. The external APR device may be used, for example, to extend a projection distance to surfaces that are too far away from the initiating APR device.

In some embodiments, the APR device may be compact and/or portable. In alternative embodiments, the APR device may comprise a foldable, interlocking or deconstructable chassis to facilitate portability.

In some embodiments, APR system arrangement 600 may further comprise a projection unit 660. Images and/or information projected by projection unit 660 may include real 3D images such as CAD sketches, user-defined templates, signs with predefined meanings known to onsite workers/supervisors, or the like. In some embodiments, the signs may comprise: legends; symbols; languages; numbers; different designated colors; and the like. In some embodiments, one or more of these signs may be projected onto a surface/wall/ceiling/floor/ground within the real scene 140 and thereby act as a comment/alert/notification/message to the users/workers/builders. In some embodiments, the projected image/information may utilize different colors to denote different plan types, for example blue for water, red for electricity, and/or green for position. In alternative embodiments, the colors may designated and/or selected so as to match the colors appearing in plans data 150.

In some embodiments, projected images/information may comprise one or more of:
Power wiring and outlets;
Ditches;
Air conditioning ducts/tubes;
Ventilation channels;
Windows;
Room and/or building beams;
Pipes channels (e.g., water, sewerage);
Elevator shafts;
Instructions (e.g., safety alerts);
Information on hidden objects (e.g., dimensions); and,
Levels and/or tile gridlines/guidance.

In some embodiments, the projected information may comprise sentences/letters in one or more languages, for example Chinese, English, and/or Spanish.

In some embodiments, information/images projected by projection unit 660 may comprise different degrees/levels of accuracy, for example due distance or projection angle. In some embodiments, the projection accuracy may vary in accordance with the position of the APR device and the position of surrounding objects/surfaces in the real scene 140. The projection accuracy may be improved, for example by the user, by automatically or manually adjusting the position of the APR device relative, or within, the real scene 140, for example so that the APR device is positioned closer to a surface. The level/degree of projection accuracy may be denoted by different colors, hashing and/or densities.

In some embodiments, the user may manually select which images/information should be projection into the real scene 140, for example by deselecting certain undesired objects/lines. In alternative embodiments, the projected image/information may comprise a tool, such as level tool, compass, ruler, or the like, which that may assist the user with their construction. In yet further embodiments, the user may move images/information from one place within the real scene 140 to another without moving the APR device. This may be achieved using one or more of: an input device coupled to the control/interface unit 650, for example a touch screen, touchpad, track-point or the like; by hand gestures; by user voice commands; or by any other appropriate means as would be apparent to those skilled in the art.

In some embodiments, a user may input commands, for example using control/interface unit 650, to instruct the APR device to project additional lines and/or other image shapes into the real scene 140. In alternative embodiments, these additional lines and/or other image shapes may not be present in the original plans data 150 and may be selectively added to the plans data 150 to yield updated plans data.

In some embodiments, the APR device may automatically update the original plans data 150 with changes, for example where data gathered by the 3D depth camera 620 and/or camera unit 630 differ from the original plans data 150. In alternative embodiments, the APR device may update the original plans data 150 according to a user decision.

In some embodiments, the APR device may be preprogrammed by a user, for example by a supervisor, manager, contractor, project manager, or the like, to deliver projected messages/notes, via projection unit 660, at specific moments/stages during a build cycle. In some embodiments, these notes/messages may comprise supplementary textual instructions and/or arrows, for example “Tuomas, please paint this wall in red”. In alternative embodiments, these notes/messages may comprise supplementary animated instructions which, for example, vary over time and possibly emphasize hazards and/or work notes/layouts to, for example, improve user safety. It will be appreciated by those skilled in the art that animated instructions may be preferable where there is a need to quickly draw a user's attention to, for example, critical design elements/criteria.

In some embodiments, the APR device may be operable to project topographical data and/or indications to assist, for example, a paver laying tiles and/or a plasterer leveling a wall. The topographical data and/or indications may comprise one or more images/points/text, possibly in differing colors, and may denote undulations/bumps/bulges and/or the curvature/slopes of a surface. In alternative embodiments, the APR device may be operable to project leveling information and/or guides, for example in the form of a fixed leveled line about a horizontal and/or vertical axis of the APR device.

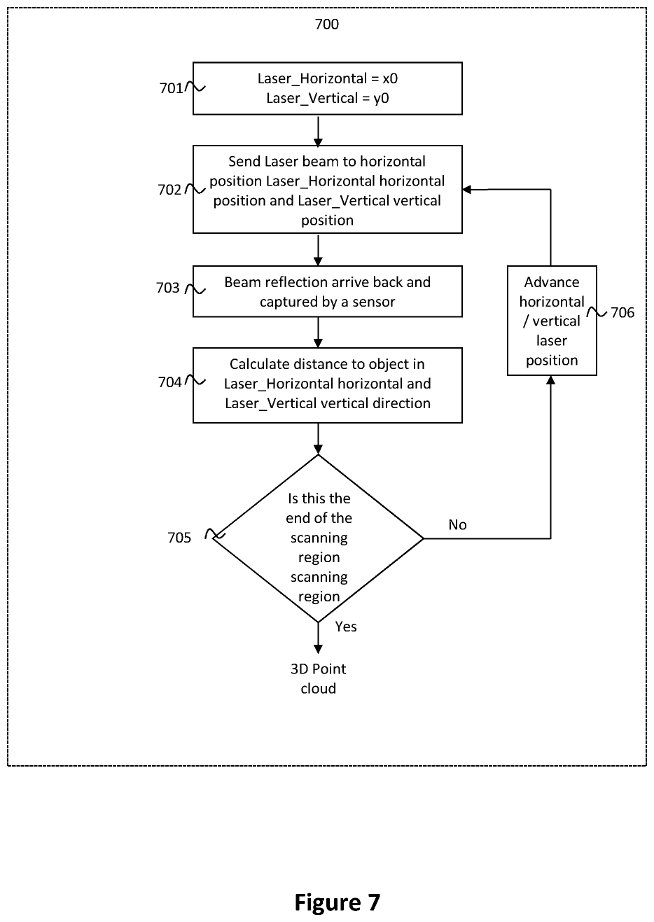

FIG. 7 is a high-level flowchart illustrating a non-limiting exemplary three-dimensional scanning method 700 according to embodiments of the invention. The method 700 may comprise the steps of: using a 3D depth camera 620 comprising a laser light beam to scan a real scene 140 represented by horizontal and vertical axis coordinates 701; directing the light beam to a first Laser_Horizontal=x0 and Laser_Vertical=y0 direction point 702; capturing, at the 3D depth camera, light beam reflections or portions thereof as they are reflected back from surfaces within the real scene 140 703; calculating the distance between the surface and APR device, in terms of Laser_Horizontal and Laser_Vertical direction 704. In the event that no reflection signal is received by the 3D depth camera, the distance is assumed to be infinity or some other maximum fixed number, and the horizontal/vertical position of the laser is advanced.

The method 700 may further comprise the step of determining whether the end of the scanning region has been reached 705 (i.e. the bounds of the real scene 140, or subsections thereof). If the end has not been reached, the method 700 may further comprise the step of advancing the Laser_Horizontal and Laser_Vertical direction point of the light beam 706. If the end has been reached, the method 700 may comprise the step of creating a 3D point cloud which represents the 3D location/position of proximate/surrounding surfaces within the real scene 140.

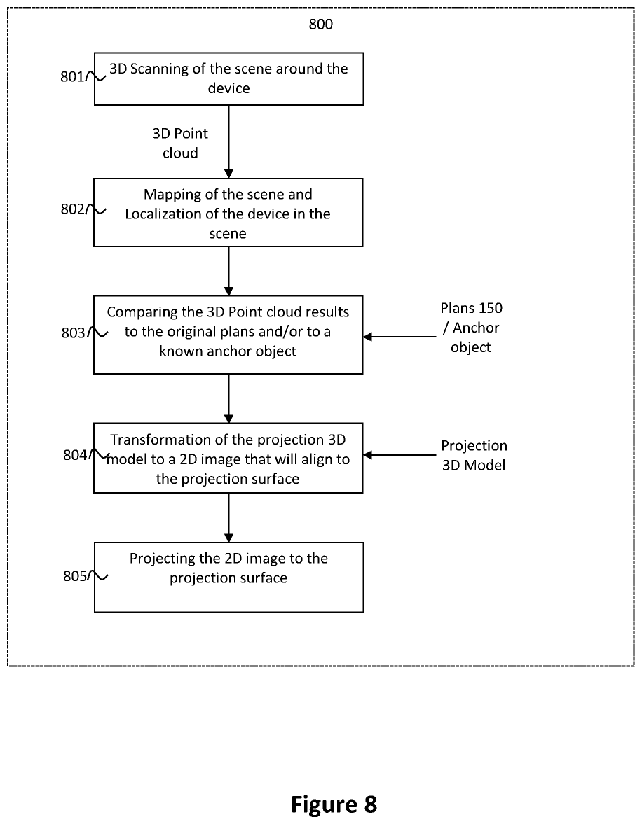

FIG. 8 is a high-level block-diagram illustrating a non-limiting exemplary method according to embodiments of the invention. The method 800 may comprise the steps of: 3D scanning the real scene 140 surrounding/proximate to the APR device and generating a 3D point cloud 801; mapping the real scene 140 around the device and localizing the position of the APR device within real scene 140 802; comparing the 3D point cloud to the original plans data 150 and/or to anchor objects to yield the exact position and orientation of the APR device 803; transforming a 3D projection model (i.e., of objects/schematics to be projected) to a 2D image that is aligned with projection surfaces in the real scene 140 804; and, projecting the 2D image onto the projection surface using the projection unit 660 805.

In some embodiments, the 3D model of surfaces is a 3D point cloud comprising a set of data points disposed throughout said scene, and the construction plan is converted and rendered into projectable visual content in accordance with the 3D point cloud.

In some embodiments, a current state of the construction may be compared with construction plans to determine a level of construction accuracy. This may entail assessing and grading, for example, a distance between desired and actual construction points, as discussed herein.

In some embodiments, the level of construction accuracy may be assessed in accordance with a misalignment threshold. The APR device may further generate one or more of: a warning indication; and, modified construction plans; in the event that said level of construction accuracy contravenes said misalignment threshold. The misalignment threshold may be a predefined or user selected value, for example concerning the distance between desired and actual construction points, representing, for example, a bound or limit on an acceptable level of divergence. In some circumstances, for example where there is significant tolerance for divergence, the misalignment threshold may be a value permitting significant divergence. In other circumstances, for example where there is a need for precision, the misalignment threshold may be a value permitting limited divergence.

In some embodiments, the construction plans may comprise a construction schedule, and the APR device may be further configured to compare a current state of the construction with the construction schedule to determine a level of construction timeliness. In particular, the construction schedule may define the timeframe in which certain aspects, tasks or portions of a construction should be completed. At various points during the construction cycle, the current state of the construction and the time elapsed may be compared with the construction schedule to determine timeliness (i.e., whether tasks have been completed in time, or whether they are overdue).

In some embodiments, the level of construction timeliness may be assessed in accordance with a construction timeline. The APR device may further generate one or more of: a warning indication; and, modified construction plans; in the event that said level of construction timeliness contravenes said construction timeline. The construction timeline may comprise predefined or user selected values concerning, for example, the order and timeframe in which certain aspects, tasks or portions of a construction should be completed. In some circumstances, for example where the construction timeliness indicates that one or more projects is overdue and/or has not been completed on time, the construction timeline may require revision or overhaul. In alternative circumstances, for example where the construction timeliness indicates optimal adherence to the construction schedule, the construction timeline may remain fit for purpose and require little or no revision.

In some embodiments, the APR device may be further configured to automatically or selectively update said projectable visual content in accordance with one or more of: a manual user input; the construction timeline; and, modified construction plans.

In some embodiments, the APR device may comprise a communication module, and may be further configured to transmit, using said communication module, one or more feedback or status updates to external or internal entities regarding at least one of: said level of construction accuracy and said level of construction timeliness.

In some embodiments, the APR device may be configured to detect whether the capturing device has been moved relative to the real scene. The capturing device, the computer processor, and the projector may also be configured to immediately repeat their operation in the event that the capturing device is determined to have been moved relative to the real scene.

In some embodiments, the capturing device, the computer processor, and the projector may be configured to periodically repeat their operation and update said projectable visual content.

In some embodiments, the capturing device may be a 2D camera operable to capture 2D images. 3D images of said scene may also be constructed by combining said 2D images with other data, for example other sensor data.

In some embodiments, the APR device further comprises a sensor operable to detect the presence of a user and/or their location, wherein said projector is configured to terminate operation in the event that the user lies between the projector and surfaces within said scene.

In some embodiments, the projectable visual content may comprise maintenance schematics, wherein the projector is operable to project the projectable visual content onto surfaces within a fully constructed building.

In some embodiments, the APR device may further comprise at least one of: an external user interface module and an internal user interface module, wherein each of said external user interface modules and internal user interface modules are configured to at least one of: issue control commands to said APR device, and display information to a user.

In some embodiments, the construction schedule may comprise a construction order, and wherein the APR device may be configured to at least one of: generate a warning indication in the event that said construction order is contravened; and, generate a projection according to said construction order.

The aforementioned flowchart and diagrams illustrate the architecture, functionality, and operation of possible implementations of systems, methods and computer program products according to various embodiments of the present invention. In this regard, each portion in the flowchart or portion diagrams may represent a module, segment, or portion of code, which comprises one or more executable instructions for implementing the specified logical function(s). It should also be noted that, in some alternative implementations, the functions noted in the portion may occur out of the order noted in the figures. For example, two portions shown in succession may, in fact, be executed substantially concurrently, or the portions may sometimes be executed in the reverse order, depending upon the functionality involved, It will also be noted that each portion of the portion diagrams and/or flowchart illustration, and combinations of portions in the portion diagrams and/or flowchart illustration, can be implemented by special purpose hardware-based systems that perform the specified functions or acts, or combinations of special purpose hardware and computer instructions.

As will be appreciated by one skilled in the art, aspects of the present invention may be embodied as a system or an apparatus. Accordingly, aspects of the present invention may take the form of an entirely hardware embodiment or an embodiment combining software and hardware aspects that may all generally be referred to herein as a “circuit,” “module” or “system.”

The aforementioned figures illustrate the architecture, functionality, and operation of possible implementations of systems and apparatus according to various embodiments of the present invention. Where referred to in the above description, an embodiment is an example or implementation of the invention. The various appearances of “one embodiment,” “an embodiment” or “some embodiments” do not necessarily all refer to the same embodiments.

Although various features of the invention may be described in the context of a single embodiment, the features may also be provided separately or in any suitable combination. Conversely, although the invention may be described herein in the context of separate embodiments for clarity, the invention may also be implemented in a single embodiment.

Reference in the specification to “some embodiments”, “an embodiment”, “one embodiment” or “other embodiments” means that a particular feature, structure, or characteristic described in connection with the embodiments is included in at least some embodiments, but not necessarily all embodiments, of the inventions. It will further be recognized that the aspects of the invention described hereinabove may be combined or otherwise coexist in embodiments of the invention.

It is to be understood that the phraseology and terminology employed herein is not to be construed as limiting and are for descriptive purpose only.

The principles and uses of the teachings of the present invention may be better understood with reference to the accompanying description, figures and examples.

It is to be understood that the details set forth herein do not construe a limitation to an application of the invention.

Furthermore, it is to be understood that the invention can be carried out or practiced in various ways and that the invention can be implemented in embodiments other than the ones outlined in the description above.

It is to be understood that the terms “including”, “comprising”, “consisting” and grammatical variants thereof do not preclude the addition of one or more components, features, steps, or integers or groups thereof and that the terms are to be construed as specifying components, features, steps or integers.

If the specification or claims refer to “an additional” element, that does not preclude there being more than one of the additional element.

It is to be understood that where the claims or specification refer to “a” or “an” element, such reference is not be construed that there is only one of that element.

It is to be understood that where the specification states that a component, feature, structure, or characteristic “may”, “might”, “can” or “could” be included, that particular component, feature, structure, or characteristic is not required to be included.

Where applicable, although state diagrams, flow diagrams or both may be used to describe embodiments, the invention is not limited to those diagrams or to the corresponding descriptions. For example, flow need not move through each illustrated box or state, or in exactly the same order as illustrated and described.

Methods of the present invention may be implemented by performing or completing manually, automatically, or a combination thereof, selected steps or tasks.

The term “method” may refer to manners, means, techniques and procedures for accomplishing a given task including, but not limited to, those manners, means, techniques and procedures either known to, or readily developed from known manners, means, techniques and procedures by practitioners of the art to which the invention belongs.

The descriptions, examples and materials presented in the claims and the specification are not to be construed as limiting but rather as illustrative only.

Meanings of technical and scientific terms used herein are to be commonly understood as by one of ordinary skill in the art to which the invention belongs, unless otherwise defined.

The present invention may be implemented in the testing or practice with materials equivalent or similar to those described herein.

While the invention has been described with respect to a limited number of embodiments, these should not be construed as limitations on the scope of the invention, but rather as exemplifications of some of the preferred embodiments. Other or equivalent variations, modifications, and applications are also within the scope of the invention. Accordingly, the scope of the invention should not be limited by what has thus far been described, but by the appended claims and their legal equivalents.

1. A system for projecting an adaptive augmented reality content over a dynamically changing construction site, the system comprising:
a capturing device comprising at least one sensor configured to capture 3D images of a scene;
a computer processor configured to:
generate a 3D model of surfaces within said scene, based on said captured 3D images; and
obtain a construction plan associated with a construction to be built in said scene;
generate projectable visual content based on:
i) a desired state of construction based on the construction plan; and,
ii) a current state of the construction based on said 3D model of surfaces within said scene; and
a projector configured to project said projectable visual content onto said surfaces within said scene,
wherein said capturing device, said computer processor, and said projector are configured to repeat their operation and update said projectable visual content.

2. A system according to claim 1, wherein said 3D model of surfaces is a 3D point cloud comprising a set of data points disposed throughout said scene, and wherein said construction plan is converted and rendered into projectable visual content in accordance with said 3D point cloud.

3. A system according to claim 1, wherein said system is further configured to compare said current state of the construction with said construction plans and therefrom determine a level of construction accuracy.

4. A system according to claim 3, wherein said processor is further configured to assess said level of construction accuracy in accordance with a misalignment threshold, and generate one or more of:
i) a warning indication; and,
ii) modified construction plans;
in the event that said level of construction accuracy contravenes said misalignment threshold.

5. A system according to claim 1, wherein said construction plans comprise a construction schedule, and wherein said system is further configured to compare said current state of the construction with said construction schedule and therefrom determine a level of construction timeliness.

6. A system according to claim 5, wherein said processor is further configured to assess said level of construction timeliness in accordance with a construction timeline, and generate one or more of:
i) a warning indication; and,
ii) modified construction plans;
in the event that said level of construction timeliness contravenes said construction timeline.

7. A system according to claim 4, wherein said processor is further configured to automatically or selectively update said projectable visual content in accordance with one or more of:
i) a manual user input;
ii) said construction timeline; and,
iii) said modified construction plans.

8. A system according to claim 3, wherein said system further comprises a communication module, and wherein said processor is further configured to transmit, using said communication module, one or more feedback or status updates to external or internal entities regarding at least one of: said level of construction accuracy and said level of construction timeliness.

9. A system according to claim 8, wherein said feedback or status updates comprise alert or warning information, and wherein said alert or warning information comprises one or more of:
i) information on construction quality;
ii) information on divergence between said current state of the construction and said construction plan;
iii) information concerning statistical or scheduling divergence;
iv) information concerning potential safety hazards;
v) information on size measurements of rooms or buildings; and,
vi) information on resource usage.

10. A system according to claim 1, wherein said projectable visual content comprises one or more of:
i) power wiring and outlets;
ii) ditches;
iii) air conditioning ducts or tubes;
iv) ventilation channels;
v) windows;
vi) room or building beams;
vii) pipe channels;
viii) elevator shafts;
ix) instructions or guidance;
x) hidden objects;
xi) levels or gridlines;
xii) walls or other surfaces; and,
xiii) templates.

11. A system according to claim 4, wherein said system further comprises a display device, and wherein said processor is further configured to generate a warning or prompt on said display device in the event that said modified construction plans are generated.

12. A system according to claim 11, wherein said system further comprises an input device, and wherein said modified construction plans may be accepted or rejected using said input device.

13. A system according to claim 1, wherein said system further comprises a sensor configured to detect whether said capturing device has been moved relative to said scene, and wherein said capturing device, said computer processor, and said projector are configured to immediately repeat their operation in the event that said capturing device is determined to have been moved relative to said scene.

14. A system according to claim 1, wherein said capturing device, said computer processor, and said projector are configured to periodically repeat their operation and update said projectable visual content.

15. A system according to claim 1, wherein said capturing device is a 2D camera operable to capture 2D images, and wherein said 3D images of said scene are constructed from a combination of said 2D images and other data.

16. A system according to claim 1, wherein said projector and said capturing device share one or more common components.

17. A system according to claim 1, wherein said system further comprises a sensor operable to detect one or more of: the presence and distance of a user, and wherein said projector is configured to terminate operation in the event that said user lies between said projector and said surfaces within said scene.

18. A system according to claim 1, wherein said projectable visual content comprises maintenance schematics, and wherein said projector is operable to project said projectable visual content onto surfaces within a fully constructed building.

19. A system according to claim 1, wherein said system further comprises at least one of: an external user interface module and an internal user interface module, and wherein each of said external user interface modules and internal user interface modules are configured to at least one of: issue control commands to said system, and display information to a user.

20. (canceled)

21. A method for projecting an adaptive augmented reality content over a dynamically changing construction site, the method comprising:
capturing, using a capturing device, 3D images of a scene;
generating a 3D model of surfaces within said scene, based on said 3D images of said scene;
obtaining a construction plan associated with a construction to be built in said scene;
generating projectable visual content based on:
i) a desired state of construction based on the construction plan; and,
ii) a current state of the construction based on said 3D model of surfaces within said scene; and
projecting said projectable visual content onto said surfaces within said scene,
wherein said capturing, said obtaining, said generating, and said projecting are repeated to update said projectable visual content.

22-40. (canceled)
